(19) United States
(12) Patent Application Publication
(10) Pub. No.: US 2024/0207889 A1
(43) Pub. Date: Jun. 27, 2024

(54) SUPPORT UNIT, FILM FORMING APPARATUS, AND CARRIER SUPPORT METHOD

(71) Applicant: Resonac Corporation, Tokyo (JP)

(72) Inventor: Takayuki Mori, Tokyo (JP)

(21) Appl. No.: 18/493,123

(22) Filed: Oct. 24, 2023

(30) Foreign Application Priority Data
Dec. 26, 2022 (JP) 2022-208785

(51) Int. Cl. B05C 13/00; B05D 1/00

(52) U.S. Cl. CPC B05C 13/00; B05D 1/002

(57) ABSTRACT

A support unit of a carrier that holds a substrate, includes a plurality of rotating members configured to support the carrier inside a chamber where a film forming process is performed on the substrate when transporting the carrier, and a support body configured to rotatably support the plurality of rotating members inside the chamber. The support body extends from an upstream side to a downstream side in a transport direction of the carrier. The plurality of rotating members are arranged on the support body in a line from the upstream side to the downstream side of the support body. An interval between adjacent rotating members of a first set disposed on one of the upstream side and the downstream side of the support body is narrower than an interval between adjacent rotating members of a second set disposed between the upstream side and the downstream side of the support body.

### CROSS-REFERENCE TO RELATED APPLICATIONS

This application is based upon and claims priority to Japanese Patent Application No. 2022-208785, filed on Dec. 26, 2022, the entire contents of which are incorporated herein by reference.

### BACKGROUND

### 1. Field of the Invention

Certain aspects of the embodiments discussed herein are related to support units, film forming apparatuses, and carrier support methods.

### 2. Description of the Related Art

In the related art, there is known a film forming apparatus that performs a film forming process a film deposition process with respect to a substrate, by transporting a carrier holding the substrate into a chamber, as proposed in Japanese Laid-Open Patent Publication No. H08-274142, for example.

In the film forming apparatus proposed in Japanese Laid-Open Patent Publication No. H08-274142, a plurality of rotating members supporting a carrier are provided inside the chamber. However, because the rotating member cannot be provided at a position where a gate valve hermetically seals the chamber, a problem may occur when transporting the carrier as the carrier passes the position of the gate valve and the carrier vibrates. When such a problem occurs during the transport of the carrier and the substrate vibrates, the substrate held by the carrier may fall from the carrier.

### SUMMARY

In view of the above problem, it is one object of the present disclosure to provide a technology to reduce vibration of a carrier that holds a substrate, and prevent falling of the substrate from the carrier.

According to one aspect of the present disclosure, there is provided a support unit of a carrier configured to hold a substrate, including a plurality of rotating members configured to support the carrier inside a chamber where a film forming process is performed on the substrate when transporting the carrier; and a support body configured to rotatably support the plurality of rotating members inside the chamber, wherein the support body extends from an upstream side to a downstream side in a transport direction of the carrier, the plurality of rotating members are arranged on the support body in a line from the upstream side to the downstream side of the support body, and an interval between adjacent rotating members of a first set disposed on one of the upstream side and the downstream side of the support body is narrower than an interval between adjacent rotating members of a second set disposed between the upstream side and the downstream side of the support body.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a cross sectional view of a recording medium manufactured by a film forming apparatus according to one embodiment;

FIG. 2 is a plan view of the film forming apparatus according to one embodiment;

FIG. 3 is a side view of a chamber of the film forming apparatus according to one embodiment;

FIG. 4A is a side view of a carrier of the film forming apparatus according to one embodiment;

FIG. 4B is a front view of the carrier of the film forming apparatus according to one embodiment;

FIG. 5A is a side view of a support unit according to one embodiment;

FIG. 5B is a plan view of the support unit according to one embodiment;

FIG. 6A is a cross sectional view of the support unit according to one embodiment; and

FIG. 6B is a partially enlarged view of the support unit according to one embodiment.

### DETAILED DESCRIPTION

Another aspect of the present disclosure provides a film forming apparatus including a carrier configured to hold a substrate; a chamber configured to perform a film forming process on the substrate; a gate valve configured to hermetically seal a space inside the chamber; a transport mechanism configured to transport the carrier inside the chamber and through the gate valve, wherein the transport mechanism includes a support unit configured to support the carrier inside the chamber, the support unit includes a plurality of rotating members configured to support the carrier inside the chamber, and a support body configured to rotatably support the plurality of rotating members inside the chamber, the support body extends from an upstream side to a downstream side in a transport direction of the carrier, the plurality of rotating members are arranged on the support body in a line from the upstream side to the downstream side of the support body, and an interval between adjacent rotating members of a first set disposed on one of the upstream side and the downstream side of the support body is narrower than an interval between adjacent rotating members of a second set disposed between the upstream side and the downstream side of the support body.

A further aspect of the present disclosure provides a method for supporting a carrier configured to hold a substrate, including preparing, including rotatably supporting a plurality of rotating members by a support body inside a chamber where a film forming process is to be performed on the substrate; and supporting the carrier inside the chamber by the plurality of rotating members when transporting the carrier, wherein the support body is disposed so as to extend from an upstream side to a downstream side in a transport direction of the carrier, the plurality of rotating members are attached to the support body so as to be arranged in a line from the upstream side to the downstream side of the support body, and an interval between adjacent rotating members of a first set disposed on one of the upstream side and the downstream side of the support body is narrower than an interval between adjacent rotating members of a second set disposed between the upstream side and the downstream side of the support body.

Hereinafter, embodiments of the present disclosure will be described in detail with reference to the drawings. In the drawings, those constituent elements that are the same are designated by the same reference numerals, and a repeated description of the same constituent elements will be omitted, as appropriate.

In recent years, the application range of a magnetic storage apparatus increased considerably, thereby increasing the importance of the magnetic storage apparatus. As a result, a recording density of a magnetic recording medium used in the magnetic storage apparatus improved considerably.

Examples of a method for manufacturing the magnetic recording medium include a method that successively forms a soft magnetic layer, an intermediate layer, a recording magnetic layer, or the like on a nonmagnetic substrate, and thereafter forms a protective layer on the recording magnetic layer, for example.

In the case of such a manufacturing method, it is preferable to continuously perform a film forming method, using a single film forming apparatus if possible. By continuously performing the film forming process, contamination of the substrate can be prevented during handling of the substrate. In addition, the number of handling steps or processes or the like can be reduced to improve an efficiency of manufacturing steps or processes, thereby improving a product yield, and increasing a productivity of the magnetic recording medium.

Accordingly, when manufacturing such a magnetic recording medium, there is a proposal to use an in-line film forming apparatus that successively forms the magnetic layer or the like on both surfaces of each of a plurality of nonmagnetic substrates, while successively transporting a carrier that holds the plurality of nonmagnetic substrates into a plurality of chambers.

In the in-line film forming apparatus, the carrier holding the plurality of substrates is successively transported to the plurality of chambers to form a multilayer structure, including multiple films, on substrate surfaces of each of the plurality of substrates. Although a large number of rotating members are used in a transport mechanism that transports the carrier, a gate valve is provided between adjacent chambers, and a rotating member cannot be provided at a position of the gate valve. Hence, a problem may occur when transporting the carrier as the carrier passes the position of the gate valve and the carrier vibrates. When such a problem occurs during the transport of the carrier and the carrier vibrates, one of the plurality of substrates held by the carrier may fall from the carrier.

Accordingly, a technique for preventing a substrate from falling will be described in one embodiment for a case where a magnetic recording medium of a hard disk device is manufactured using an in-line film forming apparatus.

### <Configuration Example of Magnetic Recording Medium>

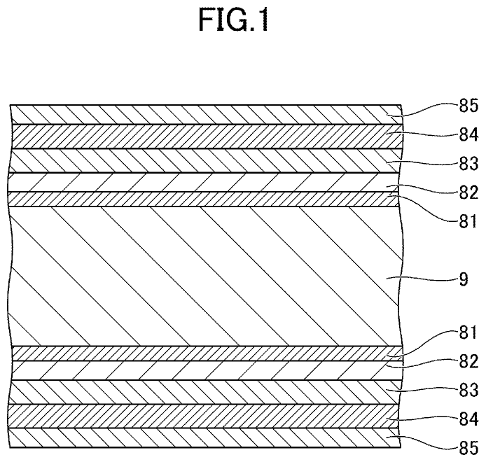

FIG. 1 is a cross sectional view of a recording medium manufactured by a film forming apparatus according to one embodiment. The recording medium is a magnetic recording medium, for example.

The magnetic recording medium has a structure including a soft magnetic layer 81, an intermediate layer 82, a recording magnetic layer 83, and a protective layer 84 that are successively laminated on both surfaces (that is, top and bottom surfaces) of a disk shaped substrate 9, and a lubricant film 85 formed on the outermost surfaces of the magnetic recording medium. The outermost surfaces include an upper surface of an upper protective layer 84, and a lower surface of a lower protective layer 84, for example.

Examples of the disk shaped substrate 9 include Al alloy substrates including Al as a main component thereof, such as Al-Mg alloys or the like, and substrates made of any one of ordinary soda glass, aluminosilicate-based glass, glass ceramics (or crystallized glass), silicon, titanium, ceramics, various resins, or the like, for example. That is, an arbitrary nonmagnetic substrate may be used for the disk shaped substrate 9.

### <Configuration Example of In-Line Film Forming Apparatus>

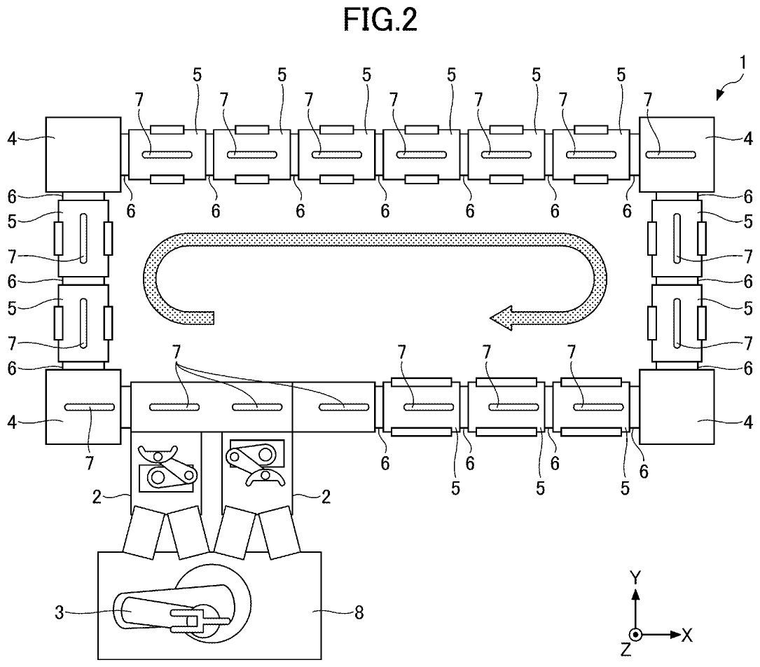

FIG. 2 is a plan view of the film forming apparatus according to one embodiment. When manufacturing the magnetic recording medium using an in-line film forming apparatus 1 illustrated in FIG. 2, for example, at least the soft magnetic layer 81, the intermediate layer 82, the recording magnetic layer 83, and the protective layer 84 are successively laminated on both surfaces of the disk shaped substrate 9 that is to be subjected to a film forming process. By successively laminating these layers 81 through 84, the magnetic recording medium can be manufactured with a high productivity.

More particularly, the in-line film forming apparatus 1 includes a robot table 8, a substrate cassette transport robot 3 placed on the robot table 8, a substrate attaching and detaching robot 2 adjacent to the robot table 8, and a plurality of corner chambers 4 that are configured to rotate a carrier 7. The in-line film forming apparatus 1 further includes a plurality of chambers 5 disposed between adjacent corner chambers 4, and a plurality of carriers 7 successively transported through the plurality of corner chambers 4 and the plurality of chambers 5.

In addition, a gate valve 6 is provided at a connecting part of each chamber 5, and the inside of each chamber 5 can become an independent hermetically sealed space when the gate valves 6 at the connecting parts thereof are in a closed state. Further, a vacuum pump (not illustrated) is connected to each chamber 5, and the inside of each chamber 5 can be controlled to a decompression state when the vacuum pump operates.

The soft magnetic layer 81, the intermediate layer 82, the recording magnetic layer 83, and the protective layer 84 are successively formed on both surfaces of the disk shaped substrate 9 that is held by the carrier 7 inside each chamber 5, while successively transporting the carrier 7 into each chamber 5 by a transport mechanism 11 which will be described later. After the protective layers 84 are formed on the disk shaped substrate 9, the disk shaped substrate 9 is unloaded from the in-line film forming apparatus 1, and the lubricant film 85 is formed on both surfaces (that is, the protective layers 84) of the disk shaped substrate 9, to finally obtain the magnetic recording medium illustrated in FIG. 1. The lubricant film 85 may be formed in the in-line film forming apparatus 1, as appropriate.

Each corner chamber 4 is a chamber that is configured to change a moving direction of the carrier 7, and a mechanism that is configured to rotate the carrier 7 and moving the rotated carrier 7 to an adjacent (or next) chamber 5 is provided in each corner chamber 4.

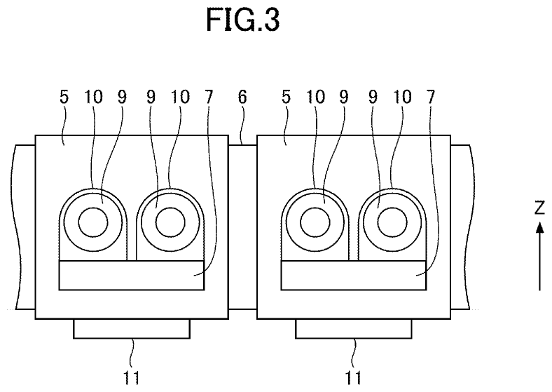

FIG. 3 is a side view of the chamber 5 of the film forming apparatus according to one embodiment. The in-line film forming apparatus 1 includes a linear motor driving mechanism that drives the carrier 7 in a non-contact state (or contactless state), for example, as the transport mechanism 11 that transports the carrier 7.

The linear motor driving mechanism includes a plurality of magnets that are disposed on a lower part of the carrier 7 so that north poles (N-poles) and south poles (S-poles) thereof are alternately arranged, and a rotary magnet disposed below the plurality of magnets via a partition wall along a transport direction so that N-poles and S-poles thereof are spirally and alternately arranged. The linear motor driving mechanism transports the carrier 7 by rotating the rotary magnet around an axis while magnetically coupling the magnets of the carrier 7 and the rotary magnet in the non-contact state.

### <Configuration Example of Carrier>

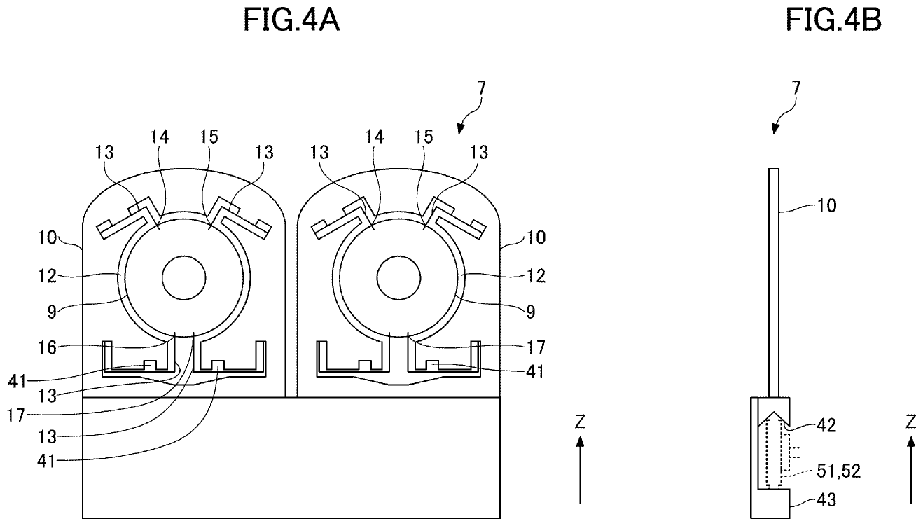

FIG. 4A and FIG. 4B are a side view and a front view of the carrier 7 of the film forming apparatus according to one embodiment, respectively. The carrier 7 is provided with a substrate holder 10 that is configured to hold the disk shaped substrate 9 in a vertical position. The vertical position refers to a state where principal surfaces (top and bottom surfaces) of the disk shaped substrate 9 are parallel to a direction in which gravity acts. Although two substrate holders 10 are disposed on the carrier 7 in the present embodiment, the number of substrate holders 10 provided on the carrier 7 is not particularly limited.

The substrate holder 10 detachably holds the disk shaped substrate 9 in a hole 12 provided on an inner side of the substrate holder 10. A plurality of support members 13 are provided in a periphery of the hole 12 of the substrate holder 10 in an elastically deformable manner. The plurality of support members 13 make contact with an outer peripheral end portion of the disk shaped substrate 9, and support the disk shaped substrate 9 that is fitted into the hole 12. Although four supporting members 13 are attached to the substrate holder 10 in the present embodiment, three or more supporting members 13 are sufficient to support the disk shaped substrate 9.

Among the four support members 13, two support members 13 located on an upper side in a vertical direction Z support a first side outer peripheral end portion 14 located on an upper left side in the vertical direction Z, and a second side outer peripheral end portion 15 located on an upper right side in the vertical direction Z, respectively. In addition, among the four support members 13, two support members 13 located on a lower side in the vertical direction Z support a third side outer peripheral end portion 16 located on a lower left side in the vertical direction Z, and a fourth side outer peripheral end portion 17 located on a lower right side in the vertical direction Z, respectively.

The support member 13 is a leaf spring member that is bent in an L-shape or a U-shape, for example. A base end of the support member 13 is fixed to a main body of the substrate holder 10, and a tip end of the support member 13 protrudes toward the inside of the hole 12. The support member 13 is disposed in a passage formed around the hole 12. A V-shaped groove or a U-shaped groove that is configured to engage the outer peripheral end of the disk shaped substrate 9 is formed at the tip end of the supporting member 13, in order to prevent the disk shaped substrate 9 from falling.

Among four passages formed around the hole 12, two passages on the lower side are provided with a release hole 41 that is configured to release the support of the disk shaped substrate 9 by the four support members 13. Two release rods (not illustrated) are inserted into the two release holes 41, respectively, to push the two lower support members 13 downward to release the support of the disk shaped substrate 9 by the two lower support members 13.

The disk shaped substrate 9 is attached to and detached from the substrate holder 10 by the substrate attaching and detaching robot 2, such as an articulated robot or the like. When attaching the disk shaped substrate 9 to the substrate holder 10, the substrate attaching and detaching robot 2 inserts the disk shaped substrate 9 that is suspended by a substrate holding member (not illustrated) into the hole 12 of the substrate holder 10, in a state where the two release rods are inserted into the two release holes 41, respectively, to push the two lower support members 13 downward. When the two lower support members 13 are released from being pushed down by the two release rods, the two lower support member 13 return to original positions thereof, and the disk shaped substrate 9 is supported by the four support members 13.

When detaching the disk shaped substrate 9 from the substrate holder 10, the substrate attaching and detaching robot 2 inserts the substrate holding member into an opening of the disk shaped substrate 9 so as not to make contact with the opening of the disk shaped substrate 9. Then, the two release rods are inserted into the two release holes 41, respectively, to push the two lower support members 13 downward to release the support of the disk shaped substrate 9 by the four support members 13, and the substrate attaching and detaching robot 2 suspends the disk shaped substrate 9 from the substrate holding member. The substrate attaching and detaching robot 2 detaches the disk shaped substrate 9 from the substrate holder 10, so that the disk shaped substrate 9 does not collide with the supporting members 13.

As illustrated in FIG. 4B, the carrier 7 is provided with a supported surface 42 that is supported from below in the vertical direction Z by a plurality of rotating members 51 and 52. The supported surface 42 extends along the transport direction of the carrier 7, and is formed in a rail shape. A cross sectional shape of the supported surface 42 is an inverted V shape or an inverted U shape, so that the rotating members 51 and 52 supporting the carrier 7 from the lower side in the vertical direction Z fit into the inverted V shape or the inverted U shape of the supported surface 42. An outer peripheral surface at an upper end of the rotating members 51 and 52 in the vertical direction Z makes contact with the supported surface 42 when transporting the carrier 7.

A linear motor driving unit 43, having a plurality of magnets so that N-poles and S-poles thereof are alternately arranged, is provided on the lower side of the carrier 7, as a part of the linear motor driving mechanism. In the present embodiment, only the rotating members 51 and 52 that support the carrier 7 from the lower side in the vertical direction Z are illustrated, but other rotating members, that are configured to support the linear motor driving unit 43 from both sides in a horizontal direction, may be provided.

### <Configuration Example of Support Unit>

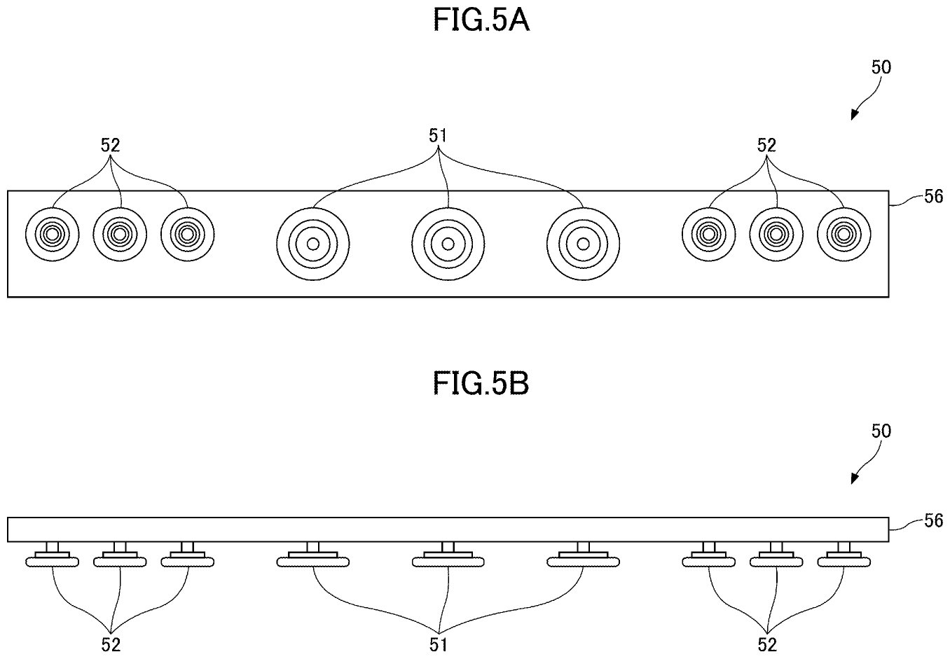

FIG. 5A and FIG. 5B are a side view and a plan view of a support unit according to one embodiment, respectively. The in-line film forming apparatus 1 includes a support unit 50 that is configured to support the carrier 7 inside the chamber 5, as the transport mechanism 11 that is configured to transport the carrier 7, for example.

The support unit 50 is provided in each chamber 5, so that the plurality of rotating members 51 and 52 are arranged in a line along the transport direction of the carrier 7. Because the gate valve 6 is provided at the connecting part of each chamber 5, the support unit 50 is not provided at the position of the gate valve 6 so that each gate valve 6 can be opened and closed.

The support unit 50 is provided with the plurality of rotating members 51 and 52, that are arranged in a line in the transport direction of the carrier 7, and make contact with the supported surface 42 of the carrier 7 when transporting the carrier 7. Further, the support unit 50 is provided with a support body 56 that is configured to rotatably support the plurality of rotating members 51 and 52 inside the chamber 5. Upper ends of the plurality of rotating members 51 and 52 in the vertical direction Z are located at the same height position. In the present embodiment, nine rotating members 51 and 52 are provided on the support body 56, but the number of rotating members 51 and 52 is not particularly limited.

The support body 56 extends from an upstream side to a downstream side in the transport direction of the carrier 7. The nine rotating members 51 and 52 are arranged in a line from the upstream side to the downstream side of the support body 56.

Rotating members 52 of a first set are rotatably supported on the upstream side and the downstream side of the support body 56. The rotating members 52 of the first set include three rotating members 52 on each of the upstream side and the downstream side of the support body 56, that is, a total of six rotating members 52 are used in the rotating members 52 of the first set. In the present embodiment, six rotating members 52 are used in the rotating members 52 of the first set, but the number of rotating members 52 of the first set is not particularly limited. In addition, the rotating members 52 of the first set may be provided on one of the upstream side and the downstream side of the support body 56.

Rotating members 51 of a second set are rotatably supported between the upstream side and the downstream side of the support body 56. The rotating members 51 of the second set include three rotating members 51 between the upstream side and the downstream side of the support body 56. In the present embodiment, three rotating members 51 are used in the rotating members 51 of the second set, but the number of rotating members 51 of the second set is not particularly limited.

In the present embodiment, an interval between adjacent rotating members 52 of the first set disposed on one of the upstream side and the downstream side of the support body 56 is narrower than an interval between adjacent rotating members 51 of the second set disposed between the upstream side and the downstream side of the support body 56. By making the interval between the adjacent rotating members 52 of the first set relatively narrow, it is possible to smoothly transport the carrier 7 from one chamber 5 and to another chamber 5, at the position of the gate valve 6 between the adjacent chambers 5. That is, because a vibration of the carrier 7 can be reduced when passing through the gate valve 6, it is possible to prevent the disk shaped substrate 9 held by the carrier 7 from falling from the carrier 7. For this reason, it is possible to provide the in-line film forming apparatus 1 having a high productivity.

In the present embodiment, a diameter of the rotating members 52 of the first set is preferably smaller than a diameter of the rotating members 51 of the second set. By making the diameter of the rotating members 52 of the first set relatively small, the interval between the rotating members 52 of the first set can be made narrower than the interval between the rotating members 51 of the second set with ease. In addition, according to such a configuration, a rotation speed (a number of rotations per unit time) of the rotating member 52 of the first set and a rotation speed of the rotating member 51 of the second set can be made different when transporting the carrier 7, and thus, the support unit 50 is less likely to generate a resonance. In other words, it is possible to prevent the vibration of the support unit 50 from being transmitted to the carrier 7, and prevent the disk shaped substrate 9 from falling from the carrier 7 due to the vibration.

Moreover, in the present embodiment, the rotating members 52 of the first set are preferably attached to the support body 56 so that the rotating members 52 of the first set are displaceable downward in the vertical direction Z with respect to the support body 56. Because the rotating members 52 of the first set are displaceable downward in the vertical direction Z, it is possible to more smoothly transport the carrier 7 from one chamber 5 and to another chamber 5, at the position of the gate valve 6 between the adjacent chambers 5. That is, because the vibration of the carrier 7 can further be reduced when passing through the gate valve 6, it is possible to more positively prevent the disk shaped substrate 9 held by the carrier 7 from falling from the carrier 7.

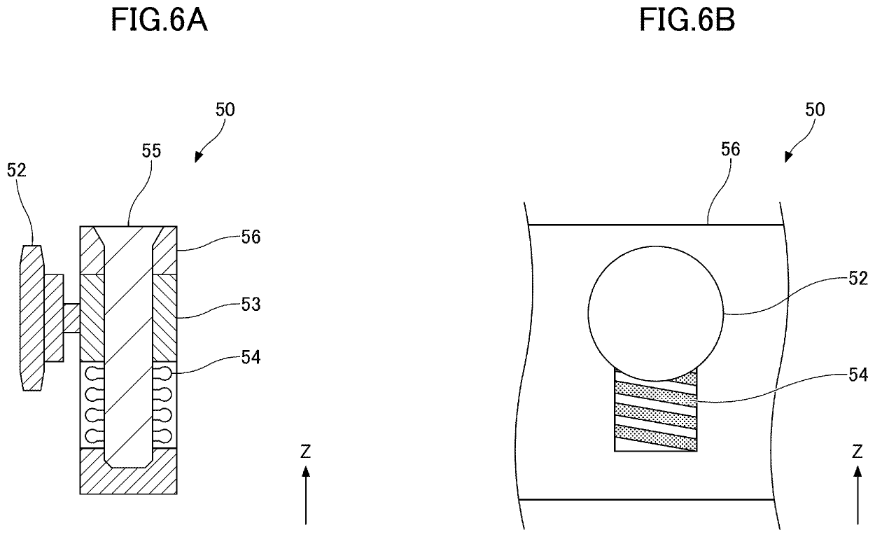

FIG. 6A and FIG. 6B are a cross sectional view and a partially enlarged view of the support unit according to one embodiment. FIG. 6A and FIG. 6B illustrate an example of a displacement mechanism that is configured to displace the rotating members 52 of the first set downward in the vertical direction Z. In the present embodiment, the rotating members 52 of the first set supporting the carrier 7 from below in the vertical direction Z is displaced downward in the vertical direction Z. However, in the case of rotating members supporting the carrier 7 from both sides in the horizontal direction, the rotating members may be configured to be displaced laterally in the horizontal direction.

The displacement mechanism includes a holding block 53 that is configured to rotatably hold the rotating member 52, a coil spring 54 that is configured to urge the holding block 53, and a stripper bolt 55 that is inserted through the holding block 53 and the coil spring 54 and is configured to be fixed to the support body 56.

The holding block 53 is an example of a holding member that is configured to rotatably hold the rotating member 52. The holding block 53 is formed to a rectangular parallelepiped shape, and has a through hole penetrating the holding block 53 in the vertical direction Z. The holding block 53 is slidably disposed in a support hole of the support body 56, and a shaft portion of the stripper bolt 55 is inserted into the through hole of the holding block 53.

The coil spring 54 is an example of an elastic member that is configured to urge the holding block 53. The coil spring 54 is disposed in the support hole of the support body 56, together with the holding block 53, and the shaft portion of the stripper bolt 55 is inserted into the coil spring 54.

The stripper bolt 55 is an example of a shaft member that is configured to hold the holding block 53 so as to be displaceable downward in the vertical direction Z. The stripper bolt 55 is inserted into an elongated hole and a counterbore of the support body 56. The shaft portion of the stripper bolt 55 is inserted through the holding block 53 and the coil spring 54, and a threaded portion of the stripper bolt 55 is screwed into a threaded portion formed at a bottom portion of the elongated hole of the support body 56.

Accordingly, the holding block 53 can be displaced downward in the vertical direction Z with respect to the support body 56. Moreover, because the holding block 53 is returned to the original position thereof by the coil spring 54, each of the rotating members 52 of the first set can be displaced up and down in the vertical direction Z by the holding block 53 with respect to the support body 56.

When transporting the carrier 7, the rotating members 52 of the first set are displaced downward in the vertical direction Z with respect to the support body 56. For this reason, it is possible to more smoothly transport the carrier 7 from one chamber 5 and to another chamber 5, at the position of the gate valve 6 between the adjacent chambers 5. That is, because the vibration of the carrier 7 can further be reduced when passing through the gate valve 6, it is possible to more positively prevent the disk shaped substrate 9 held by the carrier 7 from falling from the carrier 7.

### <Method of Supporting Carrier>

Hereinafter, a method of supporting the carrier 7 by the support unit 50 will be described, with reference to FIG. 5A and FIG. 5B.

### <Preparation Step>

First, in a preparation step or process, the plurality of rotating members 51 and 52 are rotatably supported by the support body 56 inside the chamber 5 where the film forming process is to be performed on the disk shaped substrate 9. The support body 56 is disposed so as to extend from the upstream side to the downstream side in the transport direction of the carrier 7, and the plurality of rotating members 51 and 52 are arranged in a line from the upstream side to the downstream side of the support body 56 and attached to the support body 56.

In addition, the interval between the adjacent rotating members 52 of the first set disposed at one of the upstream side and the downstream side of the support body 56 is set narrower than the interval between the adjacent rotating members 51 of the second set disposed between the upstream side and the downstream side of the support body 56.

In order to make the interval between the rotating members 52 of the first set relatively narrow, the diameter of the rotating members 52 of the first set is preferably smaller than the diameter of the rotating members 51 of the second set. Further, the rotating members 52 of the first set are preferably attached to the support body 56, so that the rotating members 52 of the first set are displaceable with respect to the support body 56.

### <Supporting Step>

Next, in a supporting step or process, the carrier 7 is supported by the plurality of rotating members 51 and 52 inside the chamber 5 when transporting the carrier 7. Because the interval between the rotating members 52 of the first set is relatively narrow, it is possible to smoothly transport the carrier 7 from one chamber 5 and to another chamber 5, at the position of the gate valve 6 between the adjacent chambers 5.

In addition, because the rotating members 52 of the first set are displaceable with respect to the support body 56, it is possible to more smoothly transport the carrier 7 from one chamber 5 and to another chamber 5, at the position of the gate valve 6 between the adjacent chambers 5. That is, because the vibration of the carrier 7 can further be reduced when passing through the gate valve 6, it is possible to more positively prevent the disk shaped substrate 9 held by the carrier 7 from falling from the carrier 7.

### <Functional Effects of Embodiment>

According to the in-line film forming apparatus 1 described above, the following functional effects can be obtained. In the present embodiment, the interval between adjacent rotating members 52 of the first set disposed on one of the upstream side and the downstream side of the support body 56 is narrower than the interval between adjacent rotating members 51 of the second set disposed between the upstream side and the downstream side of the support body 56. By making the interval between the adjacent rotating members 52 of the first set relatively narrow, it is possible to smoothly transport the carrier 7 from one chamber 5 and to another chamber 5, at the position of the gate valve 6 between the adjacent chambers 5. That is, because the vibration of the carrier 7 can be reduced when passing through the gate valve 6, it is possible to prevent the disk shaped substrate 9 held by the carrier 7 from falling from the carrier 7. For this reason, it is possible to provide the in-line film forming apparatus 1 having a high productivity.

In the present embodiment, the diameter of the rotating members 52 of the first set is preferably smaller than the diameter of the rotating members 51 of the second set. By making the diameter of the rotating members 52 of the first set relatively small, the interval between the rotating members 52 of the first set can be made narrower than the interval between the rotating members 51 of the second set with ease. In addition, according to such a configuration, the rotation speed of the rotating member 52 of the first set and the rotation speed of the rotating member 51 of the second set can be made different when transporting the carrier 7, and thus, the support unit 50 is less likely to generate a resonance. In other words, it is possible to prevent the vibration of the support unit 50 from being transmitted to the carrier 7, and prevent the disk shaped substrate 9 from falling from the carrier 7 due to the vibration.

Moreover, in the present embodiment, the rotating members 52 of the first set are preferably attached to the support body 56 so that the rotating members 52 of the first set are displaceable downward in the vertical direction Z with respect to the support body 56. Because the rotating members 52 of the first set are displaceable downward in the vertical direction Z, it is possible to more smoothly transport the carrier 7 from one chamber 5 and to another chamber 5, at the position of the gate valve 6 between the adjacent chambers 5. That is, because the vibration of the carrier 7 can further be reduced when passing through the gate valve 6, it is possible to more positively prevent the disk shaped substrate 9 held by the carrier 7 from falling from the carrier 7.

Although preferred embodiments are described above in detail, the present invention is not limited to the above described embodiments, and various modifications and substitutions can be made in the above described embodiments without departing from the scope of the present invention defined in the claims.

For example, the film forming apparatus of the present disclosure is not limited to the in-line film forming apparatus 1, and may be a film forming apparatus of another type, such as a batch-type film forming apparatus. In addition, the substrate of the present disclosure is not limited to the disk shaped substrate 9 for the magnetic recording medium, and may be a substrate for a semiconductor integrated circuit. Moreover, the shape of the substrate of the present disclosure is not limited to a disk shape.

In addition, the numbers such as ordinal numbers, quantities, units, ranges, or the like used in the description of the above described embodiments are all examples for specifically describing the technique of the present disclosure, and the present disclosure is not limited to the numbers of the examples. Further, a connection relationship between constituent elements or components is illustrated for specifically describing the technique of the present disclosure, and the connection relationship for implementing the functions of the present disclosure is not limited thereto.

According to the present disclosure, it is possible to provide a technology to reduce vibration of a carrier that holds a substrate, and prevent falling of the substrate from the carrier.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A support unit of a carrier configured to hold a substrate, the support unit comprising:
a plurality of rotating members configured to support the carrier inside a chamber where a film forming process is performed on the substrate when transporting the carrier; and
a support body configured to rotatably support the plurality of rotating members inside the chamber, wherein
the support body extends from an upstream side to a downstream side in a transport direction of the carrier,
the plurality of rotating members are arranged on the support body in a line from the upstream side to the downstream side of the support body, and
an interval between adjacent rotating members of a first set disposed on one of the upstream side and the downstream side of the support body is narrower than an interval between adjacent rotating members of a second set disposed between the upstream side and the downstream side of the support body.

2. The support unit as claimed in claim 1, wherein a diameter of the rotating members of the first set is smaller than a diameter of the rotating members of the second set.

3. The support unit as claimed in claim 1, wherein the rotating members of the first set are attached to the support body, so that the rotating members of the first set are displaceable with respect to the support body.

4. A film forming apparatus comprising:
a carrier configured to hold a substrate;
a chamber configured to perform a film forming process on the substrate;
a gate valve configured to hermetically seal a space inside the chamber;
a transport mechanism configured to transport the carrier inside the chamber and through the gate valve, wherein
the transport mechanism includes a support unit configured to support the carrier inside the chamber,
the support unit includes a plurality of rotating members configured to support the carrier inside the chamber, and a support body configured to rotatably support the plurality of rotating members inside the chamber,
the support body extends from an upstream side to a downstream side in a transport direction of the carrier,
the plurality of rotating members are arranged on the support body in a line from the upstream side to the downstream side of the support body, and
an interval between adjacent rotating members of a first set disposed on one of the upstream side and the downstream side of the support body is narrower than an interval between adjacent rotating members of a second set disposed between the upstream side and the downstream side of the support body.

5. The film forming apparatus as claimed in claim 4, wherein a diameter of the rotating members of the first set in the support unit of the transport mechanism is smaller than a diameter of the rotating members of the second set.

6. The film forming apparatus as claimed in claim 4, wherein the rotating members of the first set in the support unit of the transport mechanism are attached to the support body, so that the rotating members of the first set are displaceable with respect to the support body.

7. A method for supporting a carrier configured to hold a substrate, the method comprising:
preparing, including rotatably supporting a plurality of rotating members by a support body inside a chamber where a film forming process is to be performed on the substrate; and
supporting the carrier inside the chamber by the plurality of rotating members when transporting the carrier, wherein
the support body is disposed so as to extend from an upstream side to a downstream side in a transport direction of the carrier,
the plurality of rotating members are attached to the support body so as to be arranged in a line from the upstream side to the downstream side of the support body, and
an interval between adjacent rotating members of a first set disposed on one of the upstream side and the downstream side of the support body is narrower than an interval between adjacent rotating members of a second set disposed between the upstream side and the downstream side of the support body.

8. The method for supporting the carrier as claimed in claim 7, wherein a diameter of the rotating members of the first set is smaller than a diameter of the rotating members of the second set.

9. The method for supporting the carrier as claimed in claim 7, wherein the rotating members of the first set are attached to the support body, so that the rotating members of the first set are displaceable with respect to the support body.
